(19) United States
(12) Patent Application Publication
(10) Pub. No.: US 2007/0264508 A1
(43) Pub. Date: Nov. 15, 2007

(54) Abrasion Resistant Coatings by Plasma Enhanced Chemical Vapor Diposition

(76) Inventors: Aaron M. Gabelnick, Ithaca, NY (US); Christina A. Lambert, Midland, MI (US); John M. Warakomski, Midland, MI (US); Ludo M. Aerts, Eksaarde (BE)

Correspondence Address: THE DOW CHEMICAL COMPANY, INTELLECTUAL PROPERTY SECTION, P. O. BOX 1967, MIDLAND, MI, 48641-1967, US

(21) Appl. No.: 11/663,799

(22) PCT Filed: Oct. 6, 2005
(86) PCT No.: PCT/US05/35887

§ 371 Date: Mar. 23, 2007

Related U.S. Application Data
(60) Provisional application No. 60/623,690, filed on Oct. 29, 2004.

(51) Int. Cl. B32B 9/04; C08J 7/00; C23C 16/50

(52) U.S. Cl. 428/447; 427/489

(57) ABSTRACT

A process for preparing a multiple layer coating on the surface of an organic polymeric substrate by means of atmospheric pressure glow discharge deposition, the steps of the process comprising depositing a layer (first layer) of a plasma polymerized, optically clear, organosilicon compound and thereafter in a second step depositing a substantially uniform layer (second layer) of a polymeric siloxane or silicon oxide compound onto the exposed surface of said first layer, wherein the multiple layer coating has a thickness of at least 2.0 μm and an abrasion resistance demonstrating a change of 20 delta haze units or less after 500 Tabor cycles, measured according to ASTM D1044, CS10F wheels, 500 g weight.

### BACKGROUND OF THE INVENTION

The present invention relates to coating the exposed surface of a substrate with an abrasion resistant layer of an organosilicon compound using plasma enhanced chemical vapor deposition (PECVD), also referred to as glow discharge chemical vapor deposition, under atmospheric pressure or near atmospheric pressure conditions.

It is previously known to modify the surface of polymers such as polyolefins having an undesirably low surface energy in order to improve the surface wettability or adhesion or both, through deposition of a silicon oxide layer. Other polymers, such as polycarbonate have been similarly modified in order to provide improved chemical resistance, enhanced gas barrier, adhesion, antifog properties, abrasion resistance, static discharge, or altered refractive index.

U.S. Pat. No. 5,576,076 taught that the wettability and adhesion properties of polyolefin film can be improved by creating a deposit of a silicon oxide compound by subjecting the substrate to corona discharge at atmospheric pressure in the presence of a silane, a carrier gas, and an oxidant. U.S. Pat. No. 5,527,629 taught a similar process wherein oxygen in the form of residual air was present during the corona discharge treatment. Disadvantageously, the preferred silane in both processes, SiH₄, is readily oxidized, thereby requiring careful attention to prevent fires or the formation of silicon oxide particles.

U.S. Pat. No. 6,106,659 describes a cylinder-sleeve electrode assembly apparatus that generates plasma discharges in either an RF resonant excitation mode or a pulsed voltage excitation mode. The apparatus is operated at a rough vacuum with working gas pressures ranging from about 10 to about 760 Torr (1-100 kPa). Suitable compounds for use in the treatment included inert gases like argon and helium; oxidants such as oxygen, air, NO, N₂O, NO₂, N₂O₄, CO, CO₂ and SO₂; and treating compounds such as nitrogen, sulfur hexafluoride, tetrafluoromethane, hexafluoroethane, perfluoropropane, acrylic acid, silanes and substituted silanes, like dichlorosilane, silicon tetrachloride, and tetraethylorthosilicate.

U.S. Pat. No. 5,718,967 disclosed a process operating at reduced pressures for treating an organic polymer substrate such as polycarbonate to provide coatings by PECVD using one or more organosilicon compounds, including silanes, siloxanes and silazanes, especially tetramethyldisiloxane (TMDSO), and oxygen containing balance gases. Adhesion promoting layers formed by plasma polymerization of an organosilicon compound in the absence or substantial absence of oxygen are first prepared followed by a protective coating layer formed in the presence of a higher level of oxygen, preferably a stoichiometric excess of oxygen. Similar disclosures of processes and apparatus for use in these processes are contained in U.S. Pat. Nos. 5,298,587, 5,320,875 and 5,433,786.

In WP2003/066932, published Aug. 14, 2003, there was disclosed a corona discharge process for surface modification of a polymer substrate, especially polycarbonate or polypropylene, employing volatile organosilicon compounds. In Example 4, a two step deposition of an adhesive organosilicon layer using tetramethyldisiloxane (TMDSO), followed by deposition of a silicon oxide layer using tetraethylorthosilicate (TEOS) was disclosed. The oxidant employed in both steps was air.

Despite the advances in the art disclosed in the foregoing references, there remains a need to provide a highly adherent, abrasion resistant coating on polymeric substrates, particularly those organic polymeric substrates containing polar groups, such as poly(meth)acrylate, polyethylene terephthalate, polylactic acid, and polycarbonate containing substrates.

Jin-Kyung Choi et al., Surface and Coatings Technology, 131(1-3), pg. 136-140 (2000) disclosed that use of N₂O oxidant in a vacuum PECVD process which resulted in increased deposition rates of silicon dioxide coatings. Ward, et al., Langmuir, 19, 21 10-2114 (2003) disclosed certain polymeric siloxane coatings prepared by atmospheric PECVD techniques.

### SUMMARY OF THE INVENTION

A process for preparing a multiple layer coating on a surface of an organic polymeric substrate having a first and a second surface by means of atmospheric pressure glow discharge deposition, the steps of the process comprising depositing a layer (first layer) of a plasma polymerized, optically clear, organosilicon compound onto the surface of the organic polymeric substrate by atmospheric pressure glow discharge deposition of a gaseous mixture comprising a silicon-containing reagent and optionally an oxidant in a first step and thereafter in a second step depositing a substantially uniform layer (second layer) of a polymeric siloxane or silicon oxide compound onto the exposed surface of said first layer by atmospheric pressure glow discharge deposition of a gaseous mixture comprising an oxidant and a silicon-containing reagent, wherein the multiple layer coating has a thickness of at least 2.0 μm and an abrasion resistance less than or equal to 20 delta haze units after 500 Tabor cycles, measured according to ASTM D 1044, CS 10F wheels, 500 g weight.

The present invention additionally provides a process for preparing a multiple layer coating on a surface of an organic polymeric substrate having a first and a second surface by means of atmospheric pressure glow discharge deposition, the steps of the process comprising 1) depositing a layer (first layer) of a plasma polymerized, highly adherent organosilicon compound onto the surface of the organic polymeric substrate by atmospheric pressure glow discharge deposition of a gaseous mixture comprising a silicon-containing reagent and optionally an oxidant and thereafter 2) depositing a uniform layer (second layer) of a polymeric siloxane or silicon oxide compound onto the exposed surface of said first layer by atmospheric pressure glow discharge deposition of a gaseous mixture comprising an oxidant and a silicon-containing reagent, and thereafter repeating steps 1) and 2) at least once more to prepare a multilayer, abrasion resistant coating.

In a further embodiment, the present invention provides a process for preparing a multiple layer coating on a surface of an organic polymeric substrate having a first and a second surface by means of atmospheric pressure glow discharge deposition, the steps of the process comprising 1) depositing a layer (first layer) of a plasma polymerized, highly adherent organosilicon compound of the formula SiN_{w}CₓO_{y}H_{z} onto the surface of the organic polymeric substrate by atmospheric pressure glow discharge deposition of a gaseous mixture comprising a silicon-containing reagent and optionally an oxidant and thereafter 2) depositing a uniform layer (second layer) of a polymeric siloxane or silicon oxide compound of the formula SiN_{w′}C_{x′}O_{y′}H_{z′} onto the exposed surface of said first layer by atmospheric pressure plasma deposition of a gaseous mixture comprising an oxidant and a silicon-containing reagent, wherein:

w is a number from 0 to 1.0

x is a number from 0.1 to 3.0,

y is a number from 0.5 to 5.0,

z is a number from 0.1 to 5.0,

w′ is a number from 0 to 1.0,

x′ is a number from 0 to 1.0

y′ is a number from 1.0 to 5.0,

z′ is a number from 0.1 to 10.0,

wherein the multiple layer coating has a thickness of at least 2.0 μm, improved adhesion to the substrate compared to a single layer coating of only the silicon oxide, and an abrasion resistance less than or equal to 20 delta haze units after 500 Tabor cycles, measured according to ASTM D1044, CS10F wheels, 500 g weight. In a more preferred embodiment, steps 1) and 2) of the foregoing process are repeated at least once more to prepare a multiple layer, abrasion resistant coating, having improved flexibility, durability and surface flatness and uniformity.

In yet another embodiment of the invention there is provided a process for preparing a coating on a surface of an organic polymeric substrate having a first and a second surface by means of atmospheric pressure glow discharge deposition, the steps of the process comprising depositing a layer of a plasma polymerized, optically clear, highly adherent, organosilicon compound onto the surface of the organic polymeric substrate by atmospheric pressure glow discharge deposition of a gaseous mixture comprising a silicon-containing reagent and optionally an oxidant, wherein the conditions of the deposition are such that the layer of organosilicon compound deposited has an average thickness of at least 2.0 μm. Highly preferably, the layer of organosilicon compound is deposited onto the surface of the organic polymeric support at a linear deposition rate (that is the rate at which the substrate passes through the plasma) of at least 10 cm/min, preferably from 10 to 1000 cm/min.

Another embodiment is for any one of the abovementioned processes wherein the coatings are applied to the first and second surface of the organic polymeric substrate.

By depositing the layer of organosilicon compound onto the substrate tinder the foregoing deposition conditions, improved adhesion of the film to the substrate is obtained. It is believed, without wishing to be bound by such belief, that this result is due to the fact that reduced surface degradation of the underlying polymeric substrate results during the foregoing process. The presence of inert gases, nitrogen, or atmospheric gases during the process reduces the mean free path of charged products resulting from the plasma, resulting in diminished degradation of the substrate surface, especially reduced chain scission due to charged particles or free radicals, and possibly increased surface functionalization, due to generation of reactive chemical species or reagents, such as ozone. Additionally, alteration of the resulting organosilicon product composition, in particular, incorporation of polar functional groups therein, allows for improved flexibility of the resulting film as well as improved compatibility with polar polymeric substrates, such as polycarbonate, poly(meth)acrylate and polyacrylic acid polymers.

By the use of multiple layers, as in certain of the foregoing embodiments, the resulting film is more homogeneous and has greater surface flatness and optical clarity compared to a film of similar thickness containing only one layer. Moreover, greater uniformity of the resulting structure is achieved due to the fact that imperfections in any individual layer are masked or compensated by the presence of remaining layers of the composite.

In a preferred embodiment, the first layer in a bi-layer repeating structure is an organosiloxane that is less inclined to particle agglomeration, thereby resulting in improved leveling of the multiple layer film. Moreover, the composition includes increased polar functionality and decreased crosslink density compared to prior art compositions, thereby simultaneously providing increased bonding strength to substrates having polar functionality and improved flexibility and elongation. In addition, the second layer, which ultimately comprises the exposed surface is substantially lacking in organic moieties, and preferably is a polymeric siloxane or a silicon oxide layer that has greater hardness, toughness, and abrasion resistance.

In another embodiment of the invention, the resulting composite structure comprising the polymeric substrate and one or more layers of deposited organosilicon compound and one or more layers of polymeric siloxane or silicon oxide compound comprise a novel composition of matter. Preferred compositions possess improved abrasion resistance making the resulting structure ideally suited for use as the exposed layer of a plastic glazing structure for use in greenhouses, windows and other articles of commerce. Additionally, multiple layer structures, that is, structures containing more than one organosilicon layers alternating with more than one polymeric siloxane or silicon oxide layers, possess improved flexibility in the hard polymeric siloxane or silicon oxide layer, without substantial loss of abrasion resistant properties. Beneficially, this allows the deposition of thicker abrasion resistant layers, especially layers exceeding 2 μm in total thickness, that possess greater surface flatness and uniformity and are more resistant to breakage and delamination due to strain than a single layer of the polymeric siloxane or silicon oxide compound.

A preferred embodiment of the present invention is composite comprising a polymeric substrate comprising one or more layers having a first and a second surface, wherein the first and second surface independently have one or more layers of deposited organosilicon compound and independently have one or more layers of polymeric siloxane or silicon oxide compound, said deposited organosilicon and polymeric siloxane or silicon oxide layers exceeding 2 μm in total thickness.

### BRIEF DESCRIPTION OF DRAWINGS

FIG. 1 is an illustration of one apparatus used in the atmospheric pressure plasma deposition process.

FIG. 2 is an illustration of the side view of the electrode and counter-electrode

FIG. 3 is an illustration of the electrode with slits as outlet ports.

FIG. 4 is an illustration of an arrangement and geometry of the electrode outlet ports.

FIG. 5 is a schematic drawing of another suitable arrangement of components in an apparatus for use in an atmospheric pressure plasma deposition process.

FIG. 6 shows the increase in haze (delta haze) values of coated substrates after 500 Taber cycles as a function of thickness.

### DETAILED DESCRIPTION OF THE INVENTION

For purposes of United States patent practice, the contents of any patent, patent application, or publication referenced herein are hereby incorporated by reference in their entirety (or the equivalent US version thereof is so incorporated by reference) especially with respect to the disclosure of synthetic techniques, raw materials, and general knowledge in the art. Unless stated to the contrary, implicit from the context, or customary in the art, all parts and percents are based on weight.

If appearing herein, the term “comprising” and derivatives thereof is not intended to exclude the presence of any additional component, step or procedure, whether or not the same is disclosed herein. In order to avoid any doubt, all compositions claimed herein through use of the term “comprising” may include any additional additive, adjuvant, or compound, unless stated to the contrary. In contrast, the term, “consisting essentially of” if appearing herein, excludes from the scope of any succeeding recitation any other component, step or procedure, excepting those that are not essential to operability. The term “consisting of”, if used, excludes any component, step or procedure not specifically delineated or listed. The term “or”, unless stated otherwise, refers to the listed members individually as well as in any combination.

As used herein the term “monolithic” refers to a solid layer substantially lacking in fissures, cracks and pits. Highly desirably, the solid lacks deformities extending greater than 10 percent of the thickness of the solid layer from the surface. The term “substantially uniform” refers to a solid layer having a mean thickness greater than or equal to 80 percent of the maximum thickness and lacking deformities extending greater than 25 percent of the thickness of the solid layer from the surface. The term “silicon oxide” refers to compounds containing at least some silicon oxygen bonds including polymeric silicon oxides containing less than a stoichiometric quantity of oxygen. The term “organosilicon compound” refers to compounds containing both silicon and one or more aliphatic, cycloaliphatic or aromatic groups bonded directly to the silicon or through one or more oxygen, nitrogen or other noncarbon atoms. It is to be understood by the skilled artisan, that the formulas of the organosilicon and polymeric siloxane or silicon oxide film compositions prepared herein are empirical formulas and not molecular formulas.

The term “highly adherent” or “adhesive layer” refers to a organosil icon film deposited onto an organic polymeric substrate, optionally in combination with a polymeric siloxane or silicon oxide surface layer, which multilayer composition shows good adhesion according to ASTM D3359-87 cross-hatch tape peel adhesion test (on a 1 to 5 scale the larger the number the better the adhesion). Preferably, no delamination or loss from the substrate surface is seen after immersion in 65° C. water for 1 hour, more preferably 24 hours, and most preferably 10 days. Also preferable is that no delamination is observed after 1000 hours in a standard QUV-B weathering test. Highly desirably, the organic polymeric substrate comprises a polycarbonate, a polyolefin, or a poly(alkyl)acrylate polymer. The term “polymer” or “polymeric” refers to homopolymers and copolymers, including block or random copolymers, of any molecular weight or chain branching configuration.

Any suitable apparatus for performing atmospheric pressure plasma enhanced chemical vapor deposition can be employed in the present invention. Examples include those devices previously disclosed in U.S. Pat. No. 5,433,786, WO2003/066933, Ward et al., Langmuir, 2003 19, 2110-2114, and elsewhere. In all of the foregoing apparatuses, the organosilicon reagent compound is supplied as a vapor to a flowing stream of a gas (carrier gas) in the vicinity of an electrode, preferably by passing through or over the surface of the electrode, where a plasma is produced by electrical discharge between the electrode and a counter electrode. The amount of organosilicon reagent compound may be increased by use of heating to increase the vapor pressure thereof or by atomization using, for example, an ultrasonic atomizer. The latter method for achieving sufficient vapor pressure of the organosilicon reagent compound is preferred due to the avoidance of elevated temperatures that may approach the autoignition temperature of the gaseous mixture. Although the process is referred to as operating at atmospheric pressure, it is to be understood that pressures slightly above or below atmospheric (±20 kPa) are operable as well. Preferably the operating pressure is atmospheric or sufficiently above atmospheric pressure as needed to obtain the desired gas flow past the electrode(s).

Suitable organosilicon reagent compounds for use herein include organosilanes and silicone compounds, especially organosiloxanes. The term “silicone compound” as used herein refers to compounds containing both silicon-carbon bonds and silicon-oxygen bonds. Desirably, the compounds possess a suitable vapor pressure such that a sufficient quantity of the compound can be included in the carrier gas without use of excessive heat to volatilize the silicon-containing compound thereby approaching the autoignition temperature of the mixture. Preferred organosilicon reagent compounds for use herein include compounds of the formula: R₄Si[OSi(R′)₂]ᵣ, wherein R and R′, independently each occurrence, are hydrogen, hydroxyl, C₁₋₁₀ hydrocarbyl, or C₁₋₁₀ hydrocarbyloxy, and r is a number from 0 to 10. More preferred organosilicon reagent compounds correspond to the formula: H₂Si(R″₂)OSi(R′)₂, HₛSi(OR″)₄₋ₛ or (R″O)₃Si[OSi(OR″)₂]ₜOH, wherein R″, independently each occurrence is C₁₋₄ hydrocarbyl, preferably C₁₋₄ alkyl, most preferably methyl or ethyl, and s and t independently each occurrence are numbers from 0 to 4. Highly preferred organosilicon reagent compounds are tetraC₁₋₄alkyldisiloxanes and tetraC₁₋₄alkylorthosilicates, especially tetramethyldisiloxane (TMDSO), hexamethyldisiloxane (HMDSO) and tetraethylorthosilicate (TEOS). Most preferred silicon-containing compounds include linear and cyclic organosiloxanes such as tetraalkyldisiloxanes, hexaalkyldisiloxanes, tetraalkylcyclotetrasiloxanes and octaalkylcyclotetrasiloxanes. A most highly preferred silicon-containing compound for use as a reagent herein is tetramethyldisiloxane.

Sufficient oxidant is provided in the form of a balance gas which may be mixed with the carrier gas prior to entry into the reactor or added separately to the reactor, to produce the desired product, that is, a polymeric organosilicon compound as the first layer, or by increasing the oxidant concentration, a polymeric siloxane or silicon oxide material as the second layer. Additional components of the gaseous mixture include inert substances such as helium or argon. Suitable oxidants include O₂, O₃, NO, NO₂, N₂O, N₂O₃, and N₂O₄. The preferred oxidant is oxygen. Additional gases such as CO₂ and N₂ may be included if desired. A preferred gaseous mixture is air or a mixture of oxygen with nitrogen.

In the first step, the quantity of oxidant present is more of less severely limited depending on the ease with which the organosilicon compound may be oxidized. Preferably, the quantity of oxidant in the working gas (carrier plus balance gas) is less than 1.0 mole percent, more preferably less than 0.1 mole percent and highly preferably less than 0.01 mole percent. Most desirably, the first step is conducted in the substantial absence of an oxidant. It is to be understood that adventitious quantities of oxygen will unavoidable be present in the reaction mixture due to infiltration from the surrounding atmosphere, impurities in the gases employed, or physi-sorbed on the substrate surface. Desirably, the quantity of organosilicon compound present in the gaseous mixture is maintained in the range from at least 50 ppm, preferably at least 200 ppm, and more preferably at least 500 ppm; and not greater than 10000 ppm, preferably not greater than 8000 ppm, and more preferably not greater than 7000 ppm. Reduced quantities of organosilicon compound in the reaction mixture result in reduced rates of coating deposition while elevated levels can result in gas phase nucleation which can cause poor film quality and even powder formation in the coating.

Highly desirably, the first layer contains residual organic and/or polar functionality such as hydroxyl or hydrocarbyloxy functionality. Desirably, such functionality, comprises from 0.1 to 10 mol percent of the adhesive polymer layer. The resulting product is also believed to be less highly cross-linked than a more fully oxidized layer, thereby imparting better flexibility to the coated layer. The first layer imparts improved adhesion properties in a multiple layer film construction. Moreover, the second layer, and to some extent the first layer, desirably comprise a small but less than stoichiometric quantity of nitrogen, for example, in the form of silicon nitride functional groups. Preferably, 0<w≦10 and 0≦w′<1. Highly desirably, the resulting multilayer coating is monolithic and highly transparent.

In the process of the present invention, sufficient power density and frequency are applied to an electrode/counter electrode pair to create and maintain a glow discharge in a spacing between the electrode and counter electrode. The power density (based on electrode surface area exposed to the plasma) is preferably at least 1 W/cm², more preferably at least 5 W/cm², and most preferably at least 10 W/cm²; and preferably not greater than 200 W/cm², more preferably not greater than 100 W/cm², and most preferably not greater than 50 W/cm². The frequency is preferably at least 2 kHz, more preferably at least 5 kHz, and most preferably at least 10 kHz; and preferably not greater than 100 kHz, more preferably not greater than 60 kHz, and most preferably not greater than 40 kHz. The current applied to the electrodes may vary from 10 to 10,000 watts, preferably from 100 to 1000 watts, at potentials of 10 to 50,000 volts, preferably 100 to 20,000 volts.

The spacing between electrode and counter-electrode is sufficient to achieve and sustain a visible plasma (glow discharge), preferably at least 0.1 mm, more preferably at least 1 mm, and preferably not more than 50 mm, more preferably not more than 20 mm, and most preferably not more than 10 mm. The electrode, the counter electrode or both the electrode and the counter electrode may be fitted with a dielectric sleeve, if desired. In one embodiment, the electrode and counter electrode pair are encased within a high temperature resistant dielectric, such as a ceramic. The substrate to be coated may be supported or transported by the counter electrode or other wise supported in the vicinity of the plasma in order to be contacted or impinged by at least a portion of the plasma generated by the electrode and counter electrode. For the purposes of this invention, the terms electrode and counter electrode are used to refer to a first electrode and a second electrode, either of which can be polarized with the other being oppositely polarized or grounded. The flow of the carrier gas/balance gas together with the plasma generated in the vicinity of the electrodes causes plasma polymerized product to be deposited onto the surface of the substrate attached to the counter electrode or placed in the vicinity of an electrode pair. A suitable gap is provided between the substrate and the electrode or electrodes for exhaust of the carrier gas, by-products and unattached products. The width of the gap is adjusted to prevent incursion of excess amounts of contaminating gases, especially air.

Preferably the velocity of the total gas mixture through the electrode or electrode pair(s) is such that a stable plasma is formed allowing for uniform deposition of polymerized product. Desirably, the velocity of the gas passing through the exit ports is at least about 0.05 m/s, more preferably at least about 0.1 m/s, and most preferably at least about 0.2 m/s; and preferably not greater than about 1000 m/s, more preferably not greater than about 500 m/s, and most preferably not greater than about 200 m/s.

As defined herein “electrode” refers to a single conductive element or a plurality of conductive elements spaced sufficiently apart within a reactor equipped with sufficient gas flow to form a stable plasma when energized. Preferably, the electrode is hollow or equipped with a conduit for supply of the working gas mixture through one or more openings in the surface thereof. Thus, the term “past the electrode” refers to gas flowing through one or more inlets in the vicinity of the single element or multiple elements, past or near to a surface of the counter electrode, and past or onto the substrate to be coated through one or more outlets. Advantageously, because of the foregoing gas flow in an atmospheric pressure plasma deposition process, ablated material from the electrode or the walls of the reactor, if any, is substantially evacuated, thereby resulting in reduced surface defects and improved planarity in the resulting film.

Plasma polymerization as carried out by the process of the present invention typically results in an optically clear coating deposited on the surface of the substrate. The term “optically clear” is used herein to describe a coating having an optical clarity of at least 70 percent, more preferably at least 90 percent, and most preferably at least 98 percent and a haze value of preferably not greater than 10 percent, more preferably not greater than 2 percent, and most preferably not greater than 1 percent. Optical clarity is the ratio of transmitted-unscattered light to the sum of transmitted-unscattered and transmitted-scattered light (<2.5°). Haze is the ratio of transmitted-scattered light (>2.5°) to total transmitted light. These values are determined according to ASTM D 1003-97.

The substrate used in the present invention includes organic polymers in any form. Examples of substrates include films, sheets, fibers, and woven or non-woven fabrics of thermoplastics, such as polyolefins including polyethylene, polypropylene, and copolymerized mixtures of ethylene, propylene, and/or a C₄₋₈ α-olefin, polystyrenes, polycarbonates, polyesters including polyethylene terephthalate, polylactic acid, and polybutylene terephthalate, polyacrylates, polymetnacrylates, and interpolymers of any of the monomers employed in the foregoing polymers. The organic polymeric substrate of the present invention may comprise one or more layers and has a first and a second surface. In the process of the present invention, the first and/or second surface of the organic polymeric substrate can be coated. The coated substrate is referred to herein as a composite. A preferred substrate is polycarbonate. By the term “film” with respect to the substrate, is meant any material of any desired length or width and having a thickness from 0.001 to 0.1 cm. By the term “sheet” is meant a substrate of any desired length or width and having a thickness from 0.1 to 10 cm. It is to be understood, that the foregoing structures may comprise a laminate of one or more layers of the same or different organic polymer, and include as well any other suitable material, such as wood, paper, metal, cloth, or oxides of one or more metal or metalloids, exemplified by clay, talc, silica, alumina, silicon nitride, or stone, as one or more layers of a multilayer structure or as a component of one or more layers, with the proviso that the exposed surface of the substrate comprise one or more organic polymers. Laminates may be made by any process known in the art, for example, but not limited to, coextrusion, lamination by heat, lamination using an adhesive, and the like. A preferred laminate comprises a polycarbonate sheet and a polycarbonate film wherein the polycarbonate comprising the film contains a UV absorber. Another preferred laminate is a polycarbonate sheet having a first and a second surface wherein a polycarbonate film comprising UV absorbers is laminated to the first and second surface of the polycarbonate sheet; said polycarbonate films may have the same or different compositions. Alternatively, the film comprising the UV absorber is preferably a poly(meth)acrylate. In one embodiment, the UV absorber is grafted, copolymerized, or otherwise bound to the organic polymer.

Highly desirably, the first layer (interchangeably herein referred to as an adhesive layer) is applied directly to the surface of the substrate to be coated, which may be washed or rinsed to remove foreign material from the surface, but desirably not surface modified by application of an intermediate layer such as a sputtered metal (metallization) and without treatment to alter surface properties such as use of corona discharge, uv-light, electron beam, ozone, oxygen, or other chemical or physical treatment to oxidize the surface in the absence of a silicon compound.

The invention is particularly adapted for use with substrates comprising homopolymers of an ester of (meth)acrylic acid, copolymers of more than one ester of (meth)acrylic acid, and copolymeric derivatives of the foregoing polymers additionally comprising one or more copolymerizable comonomers. Highly preferred esters of (meth)acrylic acid include the hydrocarbyl esters, especially alkyl esters, containing from 1 to 10 carbons, more preferably from 1 to 8 carbons in each ester group. Highly preferred esters include butylacrylate and methylmethacrylate. In addition, such polymers may include a copolymerizable comonomer, especially a divalent, cross-link forming comonomer (referred to as cross-linked, poly(meth)acrylate polymers). Examples especially include the di(meth)acrylate esters of dialcohols, especially alkylene glycols and poly(alkylene)glycols.

The foregoing crosslinked polymeric compositions preferably comprise hard segments or inhomogeneous regions, such as gels, formed by polymerization, including cross-link forming polymerizations, especially under biphasic polymerization conditions. One suitable example of such reaction conditions include polymerization by use of sequential, suspension or emulsion polymerization conditions to produce separate polymer segments having a difference in chemical or physical properties such that the resulting polymer lacks homogeneity. Such polymers are known in the art and commercially available. Examples include sequentially suspension polymerized cross-linked polymers of alkyl esters of acrylic and methacrylic acid. Such polymers can be produced by first reacting an alkyl ester of acrylic acid having an alkyl group containing 2 to 8 carbon atoms with 0.1 to 5 percent, preferably 0.5 to 1.5 percent, cross-linking monomer in an aqueous suspending medium. The cross-linking monomer is a bi- or polyfunctional compound with an ability to cross-link the alkyl acrylate. Suitable cross-linking monomers are alkylene glycol diacrylates such as ethylene glycol diacrylate and 1,3-butylene glycol diacrylate. In subsequent polymerization stages, increasing proportions of 1 to 4 carbon alkyl methacrylate are used, such that the resulting polymer contains inhomogeneous hard segmented regions. Suitable emulsifying agents and free radical initiators are used. Suitable polymers can also contain minor amounts of copolymerized acrylic and methacrylic acids. For example, a useful polymer can be a rubbery, cross-linked poly(alkyl acrylate) dispersed in a continuous phase of a predominantly methacrylate polymer, optionally containing minor amounts of acrylates, acrylic acid, or methacrylic acid copolymerized therewith. Such polymers are described further in U.S. Pat. Nos. 3,562,235, 3,812,205, 3,415,796, 3,654,069, and 3,473,99, and elsewhere.

A preferred poly(meth)acrylate is a blend and/or copolymer and/or interpenetrating network of a first (meth)acrylate and a second (meth)acrylate such that at least two phases are present wherein one phase is a continuous phase and another phase is a dispersed phase and where the continuous phase has a higher Tg than the dispersed phase, preferably the continuous phase is rich in methyl methacrylate and the dispersed phase is rich in n-butyl acrylate.

The preferred polymer for use in at least the surface layer of a substrate herein is a crosslinked poly(meth)acrylate polymer, designated by the trademark KORAD™, and sold by Spartech PEP or SOLARCOAT™, sold by Aikema. In a particularly preferred embodiment, a polymer layer of such product in the form of a film is laminated to a polycarbonate sheet or film, or to a sheet or film layer of a poly(meth)acrylate polymer, which in turn may be laminated to a further polymer sheet or film layer, especially a polycarbonate layer. The resulting two or three layer construct is particularly desired for use as a plastic glazing material, especially where a UV absorbing material, such as an organic benzotriazole such as TINUVIN, available from Ciba, an organotin compound, zinc oxide, or similar material is incorporated into the surface layer. A structure in which the foregoing glazing material is constructed with the UW absorbing layer, especially an all (meth)acrylate polymer comprising from 0.01 to 10 percent UV absorbing material, especially an organic benzotriazole, exposed to the atmosphere or other source of UV radiation, possesses improved degradation resistance under exposure conditions, while the present abrasion resistant layer provides improved crazing, abrasion, and mar resistance. Suitable methods for forming polymeric laminates for use herein include use of an adhesive such as a cyanurate compound, a low molecular weight polybutylacrylate, or any other suitable adhesive to join the respective layers. Melt lamination of the respective polymers may be employed as well.

In one unique embodiment of the invention, the substrate comprises a laminate of one or more poly(meth)acrylate polymer layers and one or more polycarbonate homopolymers or copolymer layers in a thickness providing impact resistance. A preferred structure is a laminate comprising a polycarbonate layer having a first and a second surface wherein a poly(meth)acrylate layer is laminated to one surface, either the first or second surface. Another preferred structure is a polycarbonate layer having a first and second surface wherein a poly(meth)acrylate layer is laminated to both the first and second surface of the polycarbonate. In the case where there are two or more poly(meth)acrylate layers laminated to the polycarbonate layer, the layers may be the same poly(meth)acrylate polymer or different poly(meth)acrylate polymers. In particular, some such structures are sufficiently impact resistant to provide ballistic impact resistance and are known for use in bullet resistant glazing applications. In a unique application, a two layered version of the foregoing poly(meth)acrylate/polycarbonate structure is known to resist penetration from projectiles impinging on the poly(meth)acrylate side of the laminate, but are readily penetrated by projectiles impinging on the polycarbonate side thereof. Accordingly, a structure, such as an automobile, equipped with such laminated glazing, oriented with the poly(meth)acrylate layer facing the outside, possesses enhanced protection from bullets or projectiles originating outside the automobile, while allowing return fire originating inside the vehicle to be used to defend in case of attack (one-way bullet resistance). Application of the abrasion resistant coating of the present invention to exterior surface of such a structure, optionally over a film of a cross-linked poly(meth)acrylate polymer, especially KORAD198 , imparts improved abrasion resistance to such glazing material without sacrifice of ballistic impact resistance, especially one-way bullet impact resistance. Additionally, inclusion of a UV protective layer or component, desirably by incorporation in the cross-linked poly(meth)acrylate polymer layer or the poly(meth)acrylate polymer layer, imparts added lifetime and degradation resistance to the resulting structure under exposure to UV light.

The abrasion resistant coating of the invention is applied to a film or sheet of the polymeric substrate before or after formation of a laminate with other polymeric materials. In a preferred embodiment, the abrasion resistant coating is applied as a final step in a cast or extrusion, sheet or film forming process. The coated product may be thereafter cut to size, formed into desired shapes, or laminated to solid materials or substances without loss or degradation of the abrasion resistant coating.

A preferred embodiment of the present invention is composite comprising a polymeric substrate comprising one or more layers having a first and a second surface, wherein the first and second surface independently have one or more layers of deposited organosilicon compound and independently have one or more layers of polymeric siloxane or silicon oxide compound, said deposited organosilicon and polymeric siloxane or silicon oxide layers exceeding 2 μm in total thickness.

The process equipment used to apply the abrasion resistant coating may be located in an inert environment, but preferably is operated under ambient atmospheric conditions. The process is operated at atmospheric pressure with sufficient volumetric flow of working gas or the use of seals, vacuum ports or other suitable means to reduce incursion of ambient gases leading to alteration of the working gas composition. Preferably, the volumetric flow of working gas (including organosilicon compound, carrier gas, oxidant and balance gas) is from 10 to 1,500 cc/minute per cm² of electrode surface.

Any suitable electrode geometry and reactor design can be employed in the present process. For thick substrates, such as sheet material, it may be desirable that both the electrode and the counter electrode be located on the same side of the substrate to be coated. Plasma created reaction products are impinged onto the surface of the substrate after passing by the electrodes. Exhaust ports from the reactor are located near the substrate surface and spatially removed from the electrodes to permit contact of the plasma or at least the reaction products formed therein with the substrate surface before exiting the reactor. If desired, the shape of the resulting corona discharge may be modified by the use of a magnetic field as previously disclosed in the art. For thinner substrates, the counter electrode may be a conductive surface upon which the target or substrate is supported or otherwise supported on the opposite side of the substrate from the electrode. Highly desirably, the electrode and counter electrode are encased in a porous nonconductive casing and oriented in close proximity to the substrate surface to be coated. Either the substrate or the entire counter electrode containing the substrate may be moving, especially in a continuous treating process.

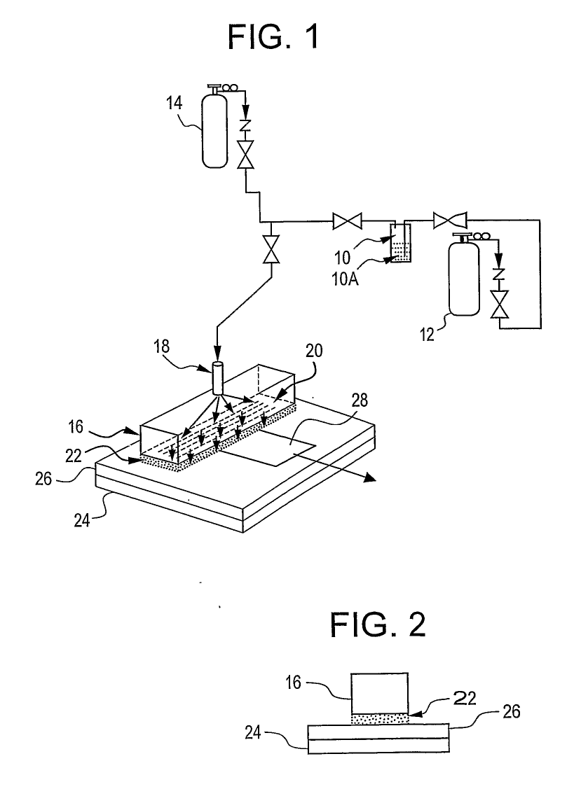

FIG. 1 provides an illustration of one apparatus used in carrying out the method of the present invention with a flexible film substrate. In FIG. 1, organosilicon compound (10) is generated from the headspace of a contained volatile liquid (10a) of the organosilicon compound, carried by a carrier gas (12) from the headspace and merged with balance gas (14) before transport to the electrode (16). The carrier gas (12) and the balance gas (14) drive the organosilicon compound (10) through the electrode (16), more particularly, through at least one inlet (18) of electrode (16), and through outlets (20), which are typically in the form of slits or holes or the gaps between a plurality of conductive elements. Power is applied to the electrode (16) to create a glow discharge (22) between the electrode (16) and the counter-electrode (24), which is optionally fitted with a dielectric layer (26). It is to be understood that the electrode (16) may also or alternatively be fitted with a dielectric sleeve (not shown in the figure). Substrate (28) is passed continuously along the dielectric layer (26) and coated with the polymeric siloxane or silicon oxide product.

FIG. 2 is a side view illustration of electrode (16), counter-electrode (24), dielectric (26) and glow discharge region (22). Where the substrate is nonconductive, the dielectric layer (26) may be omitted.

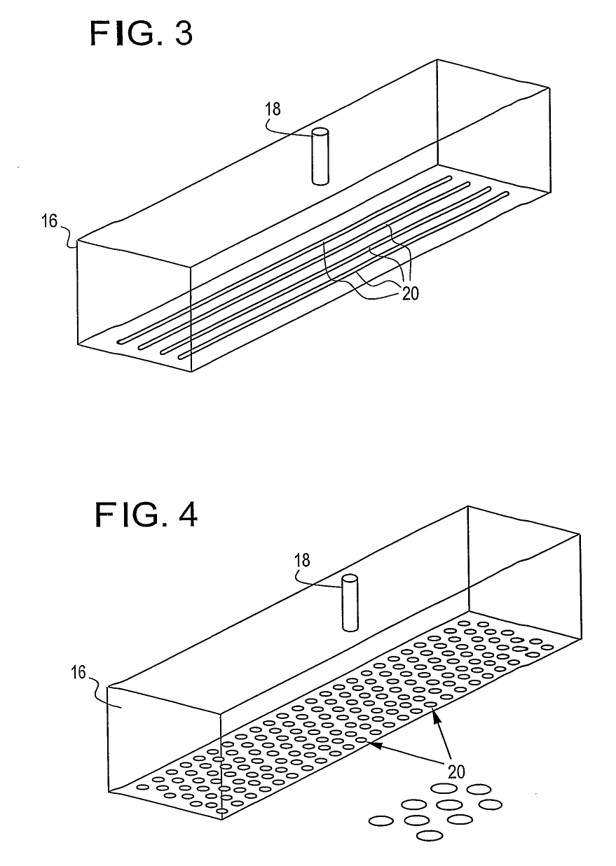

FIG. 3 is an illustration of a preferred embodiment of the electrode outlets (20), which are in the form of parallel or substantially parallel, substantially evenly spaced slits that extend approximately the length of the electrode. The width of the slits is preferably not less than 0.1 μmm, more preferably not less than 0.2 mm, and most preferably not less than 0.5 mm; and preferably not more than 10 mm, more preferably not more than 5 mm, and most preferably not more than 2 mm

FIG. 4 is an illustration of another preferred geometry and spacing of the electrode outlets (20), which are in the form of substantially circular orifices. If this geometry is used to practice the method of the present invention, the diameter of the outlets is not less than 0.05 mm, more preferably not less than 0.1 mm, and most preferably not less than 0.2 mm; and preferably not greater than 10 mm, more preferably not greater than 5 mm, and most preferably not greater than 1 mm.

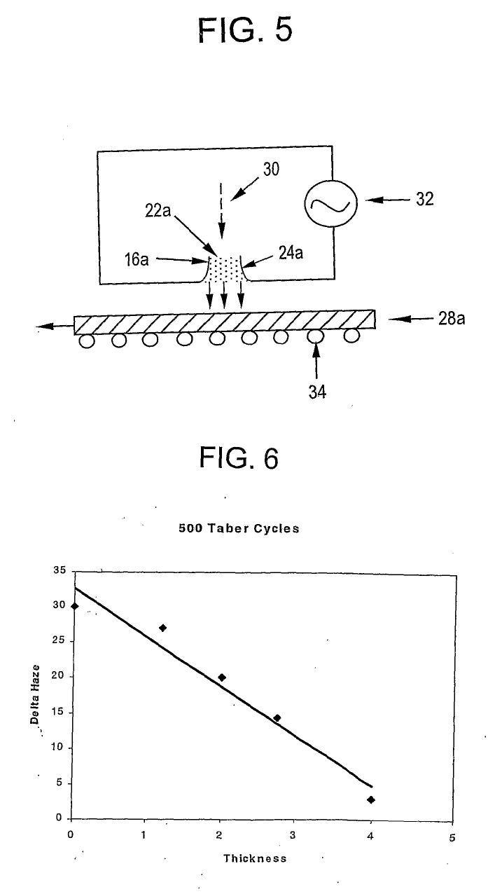

FIG. 5 is a schematic illustration of an atmospheric pressure plasma deposition process including supply means for organosilicon reagent (30), a power supply (32) connected to stationary electrode (16a) and counter electrode (24a) between which a plasma (22a) is generated. The substrate (28a) is supported by a transport mechanism such as rollers (34) and passes through at least a portion of the plasma (22a).

It has been surprisingly discovered that a multiple layer coating comprising first an organosilicon material on the substrate surface and second a contiguous polymeric siloxane or silicon oxide coating that is powder-free or substantially powder-free, can be rapidly deposited on a substrate according to the present invention. Moreover, the resulting film possesses improved abrasion resistance, greater surface smoothness and uniformity, and improved adhesion, deformation resistance and structural properties than single layer films. Desirably, the organosilicon and siloxane or silicon oxide layers each have a thickness from 0.01 μm to 1.0 μm. In total, the abrasion resistant multiple layer film of the invention desirable has a thickness from 2.0 to 10.0 μm, preferably from 2.0 to 6.0 μm, most preferably from 2.0 to 4.5 μm. Also preferably, the foregoing coating process is repeated at least twice and more preferably at least three times. Highly desirably, the resulting films are optically clear, extremely flat, and possess reduced haze. Additionally, the increase in haze (A haze) measured after 500 Taber cycles (ASTM D1044, CS10F Wheels, 500 gram weight) is 20 or less, preferably 10 or less, and most preferably 5 or less.

### EXAMPLES

The invention is further illustrated by the following example that should not be regarded as limiting of the present invention.

### Example 1

### Polycarbonate Substrate with Multiple Layer Abrasion Resistant Coating

A polycarbonate substrate is coated with a polymeric organosilicon film using the apparatus substantially as illustrated in FIG. 1. The electrodes and power supply are obtained from Corotec Industries, Farmington, Conn. The equipment is designed with a gas inlet above the discharge region which injects the working gas over an horizontally disposed electrode 10 cm in length located above a discharge zone of 1 cm height above a rotating counter electrode drum holding the substrate on its surface. The apparatus is located in a normal atmospheric environment and operated at a pressure slightly above atmospheric (1.02 kPa) to achieve discharge of gaseous products through discharge ports near the surface of the counterelectrode drum.

The substrate having a thickness of 7 mil (0.18 mm) is washed with methanol to remove surface contaminants but otherwise untreated, and supported beneath the electrode assembly. Tetramethyldisiloxane (TMDSO) is mixed with nitrogen carrier gas at 20° C. The adjusted flow rate of the TMDSO/N₂ mixture is 1000 standard cm³/min (sccm) and the flow rate of the balance gas is a mixture of N₂ (30 standard ft³/min (scfm) (850,000 sccm) and air (10 scfm, 280,000 sccm). The power supply is adjusted to 300 watts for 1 minute to provide a non-thermal arc discharge, and an organosilane coating is deposited uniformly on the exposed surface of the substrate.

The above procedure is repeated with increased oxidant level (air alone at 40 scfm, 1,100 sL/m) and reduced silane/N₂ flow (500 sccm) at a power of 900 watts to deposit a polymeric siloxane or silicon oxide coating over the organosilane coating. Substrates are coated with polymeric siloxane or silicon oxide layers of varying thicknesses by increasing or decreasing the exposure time for deposition of the second layer. For thicknesses greater than 2 μm, the preceding two step process for depositing an organosilicon layer followed by a polymeric siloxane or silicon oxide layer is repeated thereby providing a multiple layer coating having increased uniformity and surface smoothness. In addition, the multilayer coating has greater flexibility, resulting in greater durability and delamination resistance.

The resulting coated plaques are then tested for Taber abrasion resistance (ASTM D1044, 500 cycles, CS10F wheels, 500 g weight). Under the test conditions, plaques coated with a coating thickness of greater the 4 μm provide excellent abrasion resistance (A haze less than 5 percent after 500 cycles). Results are depicted in FIG. 6.

### Examples 2 to 5

### Extrusion of Acrylic Film

Extruded film was produced from four commercially available acrylic resins, sold in the form of pellets. Weight average molecular weight (Mw), number average molecular weight (Mn), and molecular weight distributions (Mw/Mn) are determined by gel permeation chromatography (GPC) in tetrahydrofuran (THF). Not all of the material dissolved; the percent soluble material was determined by the decrease in the intensity of the GPC signal compared to what would be expected if all of the material dissolved. The percent butyl acrylate was determined by carbon-13 nuclear magnet resonance (NMR). Balance is methyl methacrylate. The following acrylate resins are used:

“SOLARKOTE A 200-101” available from Arkema having an Mw of 77,000, a Mw/Mn of 1.85, and a percent butylacrylate of 18;

“SOLARKOTE P-600” available from Arkema having an Mw of 144,000, a Mw/Mn of 2.00, and a percent butylacrylate of 42;

“ACRYLITE PLUS™ ZK-6” available from Cyro having an Mw of 76,100, a Mw/Mn of 1.84, and a percent butylacrylate of 17; and

“KORAD 5005” available from Spartech PEP having an Mw of 78,000, a Mw/Mn of 2.05, and a percent butylacrylate of 31.

The pellets are dried in a desiccant dryer for 6 hours at 200° F. to a dewpoint of −28° F., then sealed in foil bags. The pellets are kept sealed until just before adding to the covered feed hopper of the extruder. The extruder is a standard 0.75 inch diameter Killion single screw extruder equipped with a 10 inch wide film die, cast roll, air knife, nip roll, and winder. The apparatus is capable of extruding up to three layers, but only one layer is made. The film thickness is controlled by adjusting the speed of the take up roller; target thickness is 150 microns with a variation of about +/− 12 microns. Extruder temperature is adjusted to keep the screw motor load less than 10 amps. Film is drawn down to about 8 inch width, however, only the inner 6 inch wide section is used due to greater thickness variation at the edges. The extruder operating conditions are shown in Table 1.

TABLE 1
Conditions for Extrusion of Acrylic Films

| | Example | | | |
|---|---|---|---|---|
| | 2 | 3 | 4 | 5 |
| | Acrylic | | | |
| | SOLARKOTE | ACRYLITE | KORAD | SOLARKOTE |
| | A200-101 | PLUS ZK-6 | 5005 | P-600 |
| Extruder rpm | 24 | 24 | 24 | 24 |
| Extruder amps | 10 | 10 | 8 | 6.5 |
| Extruder pressure, psi | 1900 | 1750 | 1750 | 1800 |
| Melt temperature, ° F. | 467 | 474 | 469 | 457 |
| Extruder Zone 1 Temperature, ° F. | 450 | 460 | 460 | 450 |
| Extruder Zone 2 Temperature, ° F. | 450 | 460 | 460 | 450 |
| Extruder Zone 3 Temperature, ° F. | 450 | 460 | 460 | 450 |
| Clamp ring temperature, ° F. | 450 | 460 | 460 | 450 |
| Adapter temperature, ° F. | 450 | 460 | 460 | 450 |
| Feedblock temperature, ° F. | 450 | 450 | 450 | 450 |
| Die Zone 1 temperature, ° F. | 450 | 450 | 450 | 450 |
| Die Zone 2 temperature, ° F. | 450 | 450 | 450 | 450 |
| Die Zone 3 temperature, ° F. | 450 | 450 | 450 | 450 |
| Cast roll speed, feet/minute | 4.0 | 3.8 | 3.8 | 3.2 |
| Cast roll temperature, ° F. | 193 | 162 | 162 | 160 |
| Film thickness, microns | 150 | 150 | 150 | 150 |

### Examples 7 to 10

### Lamination of Acrylic Film to Polycarbonate Sheet

The 150 micron thick acrylic film produced from Examples 2 to 5 and a commercially available film, “KORAD 5001” available from Spartech PEP having a butylacrylate content of 31 percent and a film thickness of 100 microns, are laminated to polycarbonate sheet

The following polycarbonate sheet is used:

“PC Sheet” is CALIBRE™ 200-10 natural polycarbonate sheet made by Dow with a thickness of 0.75 millimeter (mm).

The acrylic films are laminated onto polycarbonate sheet using an 18 inch wide Chemsultants™ benchtop roll laminator. The bottom unheated rubber roller is rotated by a motor to feed the sample, and the top metal roll is heated. The gap between the rollers is adjusted to intimately press the layers together. Residence time is controlled by the speed of the bottom roll. Polycarbonate sheet is cut into 6 inch wide by 24 inch long pieces. Acrylic film is about 8 inches wide by 28 inches long to allow for shrinkage. Acrylic film is placed on the polycarbonate sheet, and this was covered with a disposable 25 micron thick protective film of MYLAR™ poly(ethylene terephthalate). Both the acrylic film and polycarbonate sheet are fed into the laminating machine in the same direction they are extruded, commonly referred to as the “machine direction.” Roller speed control motor is set at “13.0” to provide a speed of 1-2 feet per minute. Top roll temperature was set to 340° F. for KORAD 5001, 5005, and SOLARKOTE P; 365° F. for ACRYLITE PLUS; and 375° F. for SOLARKOTE A.

Table 2 shows the multilayer sheet compositions of Examples 6 to 10 and Ex ample 11. Instrumented impact is performed on the sheet. In Table 2:

“Impact” is instrumented impact performed on an Instron™ instrumented dart impact testing machine. The polycarbonate sheet and polycarbonate sheet with laminated acrylic film are cut into 4 inch by 4 inch test specimens. The test specimens are clamped into the testing apparatus using a 1.5 inch inner diameter clamp. A 0.5 inch diameter tup strikes the sample at 8000 inches per minute. Samples are struck both on the acrylic side and on the polycarbonate side. Peak energy and total energy (both in inch-pounds) are recorded, total energy is reported in Table 2 below.

TABLE 2
Instrumented Impact of Laminated PC-Acrylic Sheet

| | PC Sheet, | | Impact-acrylic | Impact-PC side, |
|---|---|---|---|---|
| Example | 0.75 mm | Acrylic Film | side, in-lbs | In-lbs |
| 6 | PC Sheet | Ex. 4 | 116.6 | 179.1 |
| 7 | PC Sheet | KORAD | 160.1 | 175.7 |
| | | 5001 | | |
| 8 | PC Sheet | Ex. 5 | 199.3 | 164.4 |
| 9 | PC Sheet | Ex. 2 | 152.8 | 183.4 |
| 10 | PC Sheet | Ex. 3 | 114.0 | 174.6 |
| 11 | PC Sheet | none | — | 191.9 |

The acrylic surface of the multi layer polycarbonate/acrylic laminated sheets are coated with a polymeric organosilicon film using the apparatus substantially as illustrated in FIG. 1. The electrodes and power supply are obtained from Corotec Industries, Farmington, Conn. The equipment is designed with a gas inlet above the discharge region which injects the working gas over a horizontally disposed electrode 10 cm in length located above a discharge zone of 1 cm height above a rotating counter electrode drum holding the substrate on its surface. The apparatus is located in a normal atmospheric environment and operated at a pressure slightly above atmospheric (1.02 kPa) to achieve discharge of gaseous products through discharge ports near the surface of the counterelectrode drum.

The substrates having a PC sheet thickness of 0.75 mm and an acrylic film thickness of 150 microns (except for Example 7 wherein the thickness is 100 microns) are washed with an aqueous soap solution to remove surface contaminants but otherwise untreated, and supported beneath the electrode assembly. Tetramethyldisiloxane (TMDSO) in the vapor phase is mixed with nitrogen carrier gas at 20° C. The adjusted flow rate of the TMDSO/N2 mixture is 1000, 2000, or 3000 standard cm3/min (sccm) and the flow rate of the balance gas is a mixture of N2 (30 standard ft3/min (scfm) (850,000 sccm) and air (10 scfm, 280,000 sccm). The power supply is adjusted to 300 watts or 900 watts for 1 minute to provide a non-thermal arc discharge, and an organosilane coating is deposited uniformly on the exposed surface of the substrate.

The above procedure is repeated with increased oxidant level (air alone at 40 scfm, 1,100 sL/m) and reduced silane/N2 flow (500 sccm) at a power of 900 watts for 5 minutes to deposit a polymeric siloxane or silicon oxide coating over the organosilane coating. Substrates are coated with polymeric siloxane or silicon oxide layers of varying thicknesses by increasing or decreasing the exposure time for deposition of the second layer. For thicknesses greater than 2 μm, the preceding two step process for depositing an organosilicon layer followed by a polymeric siloxane or silicon oxide layer is repeated thereby providing a multiple layer coating having increased uniformity and surface smoothness. In addition, the multilayer coating has greater flexibility, resulting in greater durability and delamination resistance.

The resulting coated plaques are tested for adhesion of the plasma hard coat to the acrylic film surface. Table 3 shows the results of three different adhesion layer hard coat applied using atmospheric plasma process onto laminates of acrylic film and polycarbonate sheet. Adhesion is determined by ASTM D3359-87 crosshatch tape peel test and rated on a 0 to 5 scale where 0=no adhesion and 5=excellent adhesion.

TABLE 3
Adhesion of Atmospheric Plasma Hard Coat to PC/Acrylic Laminates

| | Condition | Condition | Condition |
|---|---|---|---|
| Example | A* (a) | B* (b) | C* (c) |
| 6 | 5 | 5 | 5 |
| 7 (d) | 5 | 5 | 5 |
| 8 | 5 | 5 | 5 |
| 9 | 4 | 4 | 5 |
| 10 | 3 | 5 | 5 |

(a) Cond. A* = 1000 sccm TMDSO/N2, 10 scfm Air, 30 scfm N2, 300 W
(b) Cond. B* = 2000 sccm TMDSO/N2, 10 scfm Air, 30 scfm N2, 900 W
(c) Cond. C* = 3000 sccm TMDSO/N2, 10 scfm Air, 30 scfm N2, 900 W
(d) Acrylic thickness is 100 microns

Under proper conditions, excellent adhesion is achieved for all of the PC/acrylic laminates.

### Example 11

### Coextrusion of Polycarbonate Sheet with Polycarbonate Film

Example 11 is a coextruded sheet comprising a 0.75 mm thick PC sheet (CALIBRE* polycarbonate 200-6 TNT resin available from The Dow Chemical Company) capped with a 125 micron film of UV stabilized PC. The CALIBRE 200-6 polycarbonate has a melt flow rate of 6 grams/10 minutes at 300° C. and 1.2 kg and the UV stabilized polycarbonate has a melt flow rate of 7 grams/10 minutes under those conditions. The UV stabilizer is a triazine UV stabilizer.

The CALIBRE 200-6 polycarbonate pellets are dried in a Conair CD-200H Compu-Dry High Heat Dehumidifying Dryer with 1000 pound capacity stainless steel hopper at 250° F. for 4 hours to a dew point of −20° F. and moisture level of 0.02 percent. Filtered dehumidified air is circulated through the pellets. The dried pellets are pneumatically conveyed to the hopper which feeds the main extruder.

The UV stabilized polycarbonate pellets are dried in a Conair CD-30H Compu-Dry High Heat Dehumidifying Dryer with 100 pound capacity stainless steel hopper at 250° F. for 4 hours to a dew point of −20° F. and moisture level of 0.02 percent. The dried pellets are manually transferred via a stainless steel bucket to the hopper which feeds the auxiliary extruder.

The sheet coextrusion system comprises a 2.5 inch diameter HPM vented main extruder (30/1 L/D) and 1.25 inch auxiliary extruder.

The main sheet extrusion system includes a 2.5 inch diameter HPM vented extruder (30/1 L/D), Magg EXTREX™ 36/36 Gear Pump, CAMILE TG Data Acquisition and Control System, and Nash MHF-120 Vacuum Pump. The extruder is water cooled and has cast bronze heaters. The screw in the primary extruder is a 2-stage Double Wave screw manufactured by HPM Corporation. The feed depth in the first stage is 0.4 inch for 5.2 diameters, the transition length is 4.4 diameters, and the metering section depth is 0.150 inch for 8.5 diameters with a 0.075 inch deep spiral barrier. The vent section is 0.45 inch deep with a length of 3.5 diameters. The second stage metering section is a double wave mixing section with a primary depth of 0.26 inch, 0.15 inch peak depth, 0.4 inch valley depth and 0.15 inch undercut depth. The length of the second stage metering section is 8 diameters. The extruder is operated with the vent closed.

A Beringer EA-20 screen changer is installed downstream of the extruder to filter impurities, increase back pressure on the extruder, and protect downstream equipment such as the gear pump from damage. A screen pack with a 40/60/80/125 mesh configuration is used. After the polymer melt is filtered, it is transported through a 25-inch long transfer line to the gear pump. The gear pump is a positive displacement device which eliminates extruder surges and delivers constant output rate, resulting in uniform sheet thickness.

The cap layer extrusion system includes a 1.25 inch auxiliary extruder. The screw in the auxiliary extruder is 24 diameters in length. The extruder is air cooled. The extruder discharges into a Maag model 24/24 gear pump. The gear pump is collected to the feedblock by a transfer line.

The two extruders feed a coextrusion feedblock to produce a two layer structure. The feedblock is manufactured by Cloeren Corporation of Orange, Tex. Once the two layer structure is created in the feedblock, the material is fed to the extrusion die which distributes the material to a sheet of desired width and thickness.

The sheet die is 26 inches wide and manufactured by Cloeren Corporation of Orange, Tex. The die has 10 temperature control zones in the body plus two lip heater zones. The lip zones are not heated in this experiment.

Extrusion rates are 100 lb/hour for the main extruder which produces the main sheet and 20 lb/hour for the auxiliary extruder which produces the cap layer. Melt temperature is 580° F.

Temperature settings for the main extruder, auxiliary extruder, gear pumps, transfer lines, and die are shown below:

2.5 inch main extruder temperature settings

| | |
|---|---|
| Extruder zone 1 | 270° C. |
| Extruder zone 2 | 280° C. |
| Extruder zone 3 | 300° C. |
| Extruder zone 4 | 300° C. |
| Extruder zone 5 | 300° C. |
| Head flange | 280° C. |
| Adapter | 280° C. |
| Screen changer | 280° C. |
| Transfer line zone 1 | 280° C. |
| Transfer line zone 2 | 280° C. |
| Transfer line zone 3 | 280° C. |
| Transfer line zone 4 | 280° C. |
| Pump inlet | 280° C. |
| Gear pump | 280° C. |
| Pump outlet | 280° C. |
| Static mixer | 280° C. |
| Elbow | 280° C. |

1.25 inch auxiliary extruder temperature settings

| | |
|---|---|
| Extruder zone 1 | 270° C. |
| Extruder zone 2 | 280° C. |
| Extruder zone 3 | 280° C. |
| Extruder zone 4 | 280° C. |
| Spool | 280° C. |
| Transfer line zone 1 | 280° C. |
| Transfer line zone 2 | 280° C. |
| Transfer line zone 3 | 280° C. |
| Pump inlet | 280° C. |
| Gear pump | 280° C. |
| Pump outlet | 280° C. |
| Elbow | 280° C. |

Sheet die temperature settings

| | |
|---|---|
| Die adapter | 280° C. |
| Die zone 1 | 280° C. |
| Die zone 2 | 280° C. |
| Die zone 3 | 280° C. |
| Die zone 4 | 280° C. |
| Die zone 5 | 280° C. |
| Die zone 6 | 280° C. |
| Die zone 7 | 280° C. |
| Die zone 8 | 280° C. |
| Die zone 9 | 280° C. |
| Die zone 10 | 280° C. |

The multi-position polishing rollstack is manufactured by Sterling, a division of Davis-Standard, Edison, N.J. The roll stack has three chrome rolls with a highly polished mirror surface finish (0.5-1.0 micro inch surface roughness). Each roll is 16 inches in diameter and 28 inches wide. Internal spiral baffles create high turbulence for the heat transfer fluid circulating in the system to maintain a temperature tolerance of +/−1° F. The multi-position rollstack is used in the horizontal position. Temperature settings are front roll (nearest to die)=260° F., middle roll =295° F., and rear roll =310° F.

Molten polymer from the die drops into the front nip point between the front roll and middle roll, then is transported up between the middle roll and back roll. The sheet is conveyed horizontally by a set of pull rolls.

The middle roll speed is about 100 inch/min, and front and back roll speeds are set at ratios of 0.90 to 1.02 of the middle roll speed. The pull roll speed is set at a ratio of about 0.90 of the back roll speed.

A protective film is applied to the top and bottom of the sheet to prevent damage to the surface of the sheet during handling, transport, and storage. The film is 2 mil thick polyethylene LDF 550, corona treated to promote adhesion. This protective film is peeled off before plasma coating.

Finished sheet is cut to length with a Famco model E13666-P-1024 guillotine shear cutter. The 24-inch wide blades are driven by an electric motor, have a 90° cutting edge, with blade clearance of 0.001 inch.

The coextruded PC substrate is washed with an aqueous soap solution to remove surface contaminants but otherwise untreated, and supported beneath the electrode assembly. Tetramethyldisiloxane (TMDSO) is mixed with nitrogen carrier gas at 20° C. The adjusted flow rate of the TMDSO/N₂ mixture is 1000 standard cm³/min (sccm) and the flow rate of the balance gas is a mixture of N₂ (30 standard ft³/min (scfm) (850,000 sccm) and air (10 scfm, 280,000 sccm). The power supply is adjusted to 300 watts for 1 minute to provide a non-thermal arc discharge, and an organosilane coating is deposited uniformly on the exposed surface of the substrate.

The above procedure is repeated with increased oxidant level (air alone at 40 scfm, 1,100 sL/m) and reduced silane/N₂ flow (500 sccm) at a power of 900 watts to deposit a polymeric siloxane or silicon oxide coating over the organosilane coating. Substrates are coated with polymeric siloxane or silicon oxide layers of varying thicknesses by increasing or decreasing the exposure time for deposition of the second layer. For thicknesses greater than 2 μm, the preceding two step process for depositing an organosilicon layer followed by a polymeric siloxane or silicon oxide layer is repeated thereby providing a multiple layer coating having increased uniformity and surface smoothness. In addition, the multilayer coating has greater flexibility, resulting in greater durability and delamination resistance.

1. A process for preparing a multiple layer coating on a surface of an organic polymeric substrate having a first and a second surface by means of atmospheric pressure glow discharge deposition, the steps of the process comprising depositing a layer (first layer) of a plasma polymerized, optically clear, organosilicon compound onto the surface of the organic polymeric substrate by atmospheric pressure glow discharge deposition of a gaseous mixture comprising a silicon-containing reagent and optionally an oxidant in a first step and thereafter in a second step depositing a substantially uniform layer (second layer) of a polymeric siloxane or silicon oxide compound onto the exposed surface of said first layer by atmospheric pressure glow discharge deposition of a gaseous mixture comprising an oxidant and a silicon-containing reagent, wherein the multiple layer coating has a thickness of at least 2.0 μm, and an abrasion resistance demonstrating a change of less than or equal to 20 delta haze units after 500 Tabor cycles, measured according to ASTM D1044, CS10F wheels, 500 g weight.

2. A process for preparing a multiple layer coating on a surface of an organic polymeric substrate having a first and a second surface by means of atmospheric pressure glow discharge deposition, the steps of the process comprising 1) depositing a layer (first layer) of a plasma polymerized, highly adherent organosilicon compound onto the surface of the organic polymeric substrate by atmospheric pressure glow discharge deposition of a gaseous mixture comprising a silicon-containing reagent and optionally an oxidant and thereafter 2) depositing a uniform layer (second layer) of a polymeric siloxane or silicon oxide compound onto the exposed surface of said first layer by atmospheric pressure glow discharge deposition of a gaseous mixture comprising an oxidant and a silicon-containing reagent, and thereafter repeating steps 1) and 2) at least once more to prepare a monolithic, multilayer, abrasion resistant coating.

3. A process for preparing a multiple layer coating on a surface of an organic polymeric substrate having a first and a second surface by means of atmospheric pressure glow discharge deposition, the steps of the process comprising 1) depositing a layer (first layer) of a plasma polymerized, highly adherent organosilicon compound of the formula SiN_{w}CₓO_{y}H_{z} onto the surface of the organic polymeric substrate by atmospheric pressure glow discharge deposition of a gaseous mixture comprising a silicon-containing reagent and optionally an oxidant and thereafter 2) depositing a uniform layer (second layer) of a polymeric siloxane or silicon oxide compound of the formula SiN_{w′}C_{x′}O_{y′}H_{z′} onto the exposed surface of said first layer by atmospheric pressure plasma deposition of a gaseous mixture comprising an oxidant and a silicon-containing reagent, wherein:
w is a number from 0 to 1.0
x is a number from 0.1 to 3.0,
y is a number from 0.5 to 5.0,
z is a number from 0.1 to 5.0,
w′ is a number from 0 to 1.0,
x′ is a number from 0 to 1.0
y′ is a number from 1.0 to 5.0,
z′ is a number from 0.1 to 10.0,
wherein the multiple layer coating has a thickness of at least 2.0 μm, improved adhesion to the substrate, and an abrasion resistance less than or equal to 20 delta haze units after 500 Tabor cycles, measured according to ASTM D1044, CS10F wheels, 500 g weight.

4. The process of claim 3 wherein steps 1) and 2) are repeated at least once more to prepare a multiple layer, abrasion resistant coating, having improved flexibility, durability and surface flatness and uniformity.

5. A process for preparing a coating on a surface of an organic polymeric substrate having a first and a second surface by means of atmospheric pressure glow discharge deposition, the steps of the process comprising depositing a layer of a plasma polymerized, optically clear, highly adherent, organosilicon compound onto the surface of the organic polymeric substrate by atmospheric pressure glow discharge deposition of a gaseous mixture comprising a silicon-containing reagent and optionally an oxidant, wherein the conditions of the deposition are such that the layer of organosilicon compound deposited has an average thickness of at least 2.0 μm.

6. The process of claim 5 wherein the layer of organosilicon compound is deposited onto the surface of the organic polymeric support at a linear deposition rate of at least 10 cm/min.

7. The process of any one of claims 1-6 wherein the second layer is substantially lacking in organic moieties.

8. A composite structure comprising a polymeric substrate having a first and a second surface, wherein the first and/or second surface has one or more layers of deposited organosilicon compound and one or more layers of polymeric siloxane or silicon oxide compound, said deposited organosilicon and polymeric siloxane or silicon oxide layers exceeding 2 μm in total thickness.

9. A composite structure according to claim 8 wherein the polymeric substrate is one or more polycarbonate layer in the form of a film and/or sheet.

10. A composite structure according to claim 8 wherein the polymeric substrate is one or more poly(meth)acrylate layer in the form of a film and/or sheet.

11. A composite structure according to claim 8 wherein the polymeric substrate is a laminate comprising one or more polycarbonate and one or more poly(meth)acrylate layers in the form of a film or sheet and the deposited organosilicon and polymeric siloxane or silicon oxide layers are adhered to the poly(meth)acrylate layer.

12. A composite structure according to claim 10 or 11 wherein the one or more poly(meth)acrylate polymer layers comprises a cross-linked poly(meth)acrylate polymer.

13. A composite structure according to claim 9, 10, 11, or 12 wherein the one or more of the polycarbonate layers and/or one or more of the poly(meth)acrylate layers additionally comprise one or more UV absorbing compounds.

14. A glazing material in the form of a sheet, laminate, extruded structure, or assembly comprising composite structure according to claim 11 or 12.

15. A glazing material in the form of a sheet, laminate, extruded structure, or assembly comprising composite structure according to claim 13.

16. An automobile or building comprising a glazing material according to claim 14.

17. An automobile or building comprising a glazing material according to claim 15

18. The automobile or building according to claim 16 wherein the glazing material is oriented with the exposed surface of the polymeric siloxane or silicon oxide coating toward the exterior of the building or automobile.

19. The automobile or building according to claim 17 wherein the glazing material is oriented with the exposed surface of the polymeric siloxane or silicon oxide coating toward the exterior of the building or automobile.

20. The composite structure according to claim 13 wherein the UV absorber is grafted, copolymerized, or otherwise bound to one or more of the polycarbonate layers and/or one or more of the poly(meth)acrylate layers.

21. The process of any one of claims 1 to 7 where the coating is applied to the first and second surface of the organic polymeric substrate.

22. The composite structure according to claim 8 wherein the first and second surface of the organic polymeric substrate independently have one or more layers of deposited organosilicon compound and independently have one or more layers of polymeric siloxane or silicon oxide compound, said deposited organosilicon and polymeric siloxane or silicon oxide layers exceeding 2 μm in total thickness.

23. The composite structure according to claim 10 wherein the poly(meth)acrylate is a blend and/or copolymer and/or interpenetrating network of a first (meth)acrylate and a second (meth)acrylate such that at least two phases are present wherein one phase is a continuous phase and another phase is a dispersed phase and where the continuous phase has a higher Tg than the dispersed phase.

24. The composite structure according to claim 23 wherein the continuous phase is rich in methyl methacrylate and the dispersed phase is rich in n-butyl acrylate.
